(19) United States
(12) Patent Application Publication
(10) Pub. No.: US 2025/0284192 A1
(43) Pub. Date: Sep. 11, 2025

(54) PATTERN FORMING METHOD AND METHOD OF MANUFACTURING SEMICONDUCTOR DEVICE

(71) Applicant: Kioxia Corporation, Tokyo (JP)

(72) Inventors: Masanori HIROSE, Mie Mie (JP); Masayuki HATANO, Yokkaichi Mie (JP); Motofumi KOMORI, Yokkaichi Mie (JP)

(73) Assignee: Kioxia Corporation, Tokyo (JP)

(21) Appl. No.: 18/828,164

(22) Filed: Sep. 9, 2024

(30) Foreign Application Priority Data
Mar. 11, 2024 (JP) 2024-037605

(51) Int. Cl. G03F 7/00; B29C 43/02; B29C 43/18; B29C 43/20; B29L 31/34; H01L 21/027

(52) U.S. Cl. CPC G03F 7/0002; B29C 43/021; B29C 43/18; B29C 43/203; H01L 21/0271; B29L 2031/3406

(57) ABSTRACT

A pattern forming method includes: forming a first layer on an object, the first layer containing a first photocurable composition; forming a second layer on the first layer, the second layer containing a second photocurable composition different in composition from the first photocurable composition; pressing a first template having a surface with a pattern against the second layer, to bring the pattern into contact with a foreign matter inside or on a surface of the second layer, thereby moving at least part of the foreign matter into the first layer; and applying a first light to the first layer and the second layer through the first template to cure the first layer and the second layer.

### CROSS-REFERENCE TO RELATED APPLICATION

This application is based upon and claims the benefit of priority from Japanese Patent Application No. 2024-037605, filed on Mar. 11, 2024; the entire contents of which are incorporated herein by reference.

### FIELD

Embodiments relate to a pattern forming method and a method of manufacturing a semiconductor device.

### BACKGROUND

A known example method of manufacturing a semiconductor device uses a technique of forming a fine pattern using nanoimprint lithography (NIL).

### BRIEF DESCRIPTION OF THE DRAWINGS

FIG. 1 is a perspective view for explaining an example structure of a template.

FIG. 2 is a schematic cross-sectional view for explaining the example structure of the template.

FIG. 3 is a schematic plan view for explaining an example of an object.

FIG. 4 is a schematic cross-sectional view for explaining a first embodiment.

FIG. 5 is a schematic cross-sectional view for explaining the first embodiment.

FIG. 6 is a schematic cross-sectional view for explaining the first embodiment.

FIG. 7 is a schematic cross-sectional view for explaining the first embodiment.

FIG. 8 is a schematic cross-sectional view for explaining the first embodiment.

FIG. 9 is a schematic cross-sectional view for explaining the first embodiment.

FIG. 10 is a schematic cross-sectional view for explaining the first embodiment.

FIG. 11 is a schematic cross-sectional view for explaining the first embodiment.

FIG. 12 is a schematic cross-sectional view for explaining the first embodiment.

FIG. 13 is a schematic cross-sectional view for explaining the first embodiment.

FIG. 14 is a schematic cross-sectional view for explaining a further embodiment of the first embodiment.

FIG. 15 is a schematic cross-sectional view for explaining the further embodiment of the first embodiment.

FIG. 16 is a schematic cross-sectional view for explaining the further embodiment of the first embodiment.

FIG. 17 is a schematic cross-sectional view for explaining the further embodiment of the first embodiment.

FIG. 18 is a schematic cross-sectional view for explaining a second embodiment.

FIG. 19 is a schematic cross-sectional view for explaining the second embodiment.

FIG. 20 is a schematic cross-sectional view for explaining the second embodiment.

FIG. 21 is a schematic cross-sectional view for explaining the second embodiment.

### DETAILED DESCRIPTION

A pattern forming method in an embodiment includes: forming a first layer on an object, the first layer containing a first photocurable composition; forming a second layer on the first layer, the second layer containing a second photocurable composition different in composition from the first photocurable composition; pressing a first template having a surface with a pattern against the second layer, to bring the pattern into contact with a foreign matter inside or on a surface of the second layer, thereby moving at least part of the foreign matter into the first layer; and applying a first light to the first layer and the second layer through the first template to cure the first layer and the second layer.

Embodiments will be hereinafter explained with reference to the drawings. A relation between the thickness and planar dimension of each of components illustrated in the drawings, a thickness ratio among the components, and so on may be different from actual ones. Further, in the embodiments, substantially the same components are denoted by the same reference signs and an explanation thereof is omitted where appropriate.

A pattern formation method using NIL includes pressing a pattern of an original plate, which is called a template, onto an imprint material layer such as an ultraviolet curable resin on an object, and applying light such as ultraviolet light to the imprint material layer to cure it and thus transferring the pattern to the imprint material layer.

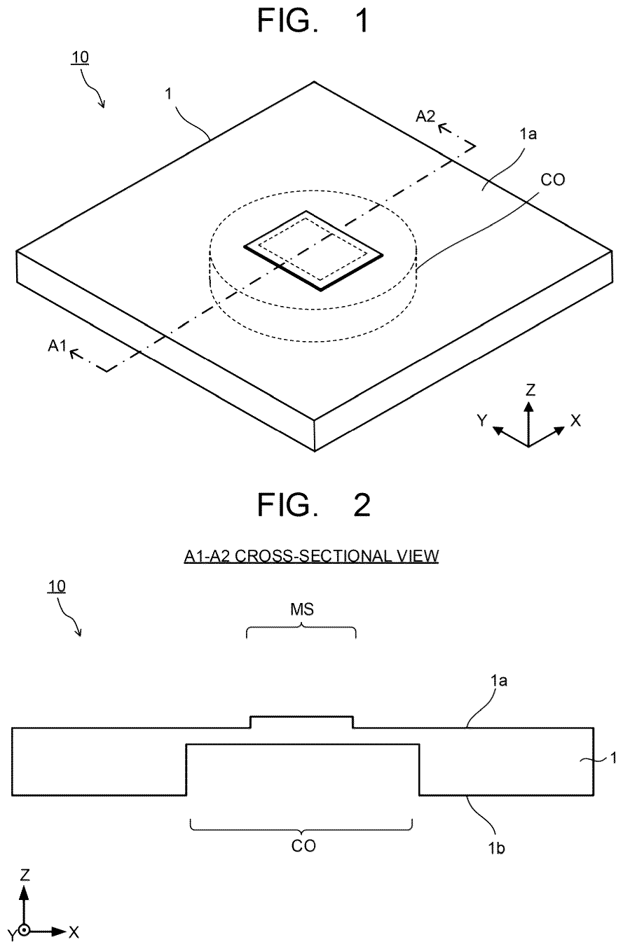

FIG. 1 is a perspective view for explaining an example structure of the template. FIG. 2 is a schematic cross-sectional view for explaining the example structure of the template. FIG. 1 and FIG. 2 illustrate a template 10. FIG. 1 and FIG. 2 illustrate an X-axis, a Y-axis orthogonal to the X-axis, and a Z-axis orthogonal to each of the X-axis and the Y-axis. FIG. 2 illustrates a part of a cross-section taken along a line segment A1-A2 illustrated in FIG. 1.

The template 10 includes a substrate 1 having a surface la and a surface 1b as illustrated in FIG. 1 and FIG. 2, the surface la having a mesa MS, and the surface 1b having a depression CO. The mesa MS is a portion where a device pattern is to be formed. Examples of the device pattern are not particularly limited and may include a line-and-space pattern and a pillar pattern. Example planar shapes of the mesa MS are not particularly limited and may include a rectangular shape. The surface la is a principal surface.

The substrate 1 contains, for example, quartz glass. The substrate 1 preferably transmits the aforementioned light.

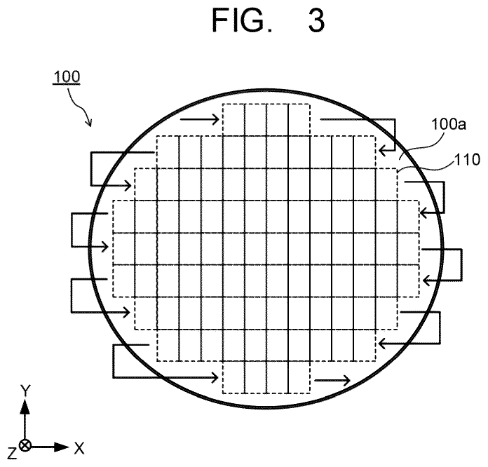

FIG. 3 is a schematic plan view for explaining an example of the object. FIG. 3 illustrates an object 100. The object 100 has a surface 100a. The surface 100a is orthogonal to a Z-axis direction. A thickness direction of the object 100 is, for example, the Z-axis direction.

The object 100 is, for example, a stack formed by stacking films on a substrate such as a silicon wafer. The films include a conductive film or/and an insulating film. The stack is, for example, a device wafer (semiconductor substrate) in the middle of manufacturing a semiconductor device. Examples of the semiconductor device include a semiconductor memory device such as a NAND flash memory, an electrical device having a microstructure such as a microelectromechanical system (MEMS), and a magnetic recording medium. The configuration of the object 100 is not limited to the above configuration.

The surface 100a has a shot area 110. The shot area 110 is a unit area to which patterns are transferred all at once by pressing the template 10 against an imprint material layer in one imprint. FIG. 3 illustrates a plurality of the shot areas 110 on the surface 100a. The shot areas 110 are arrayed along an X-Y plane of the substrate. The shot areas 110 to be imprinted are selected, for example, in an order along arrows in FIG. 3 using an imprint apparatus for performing imprint. The surface 100a may have a space among the shot areas 110.

### First Embodiment

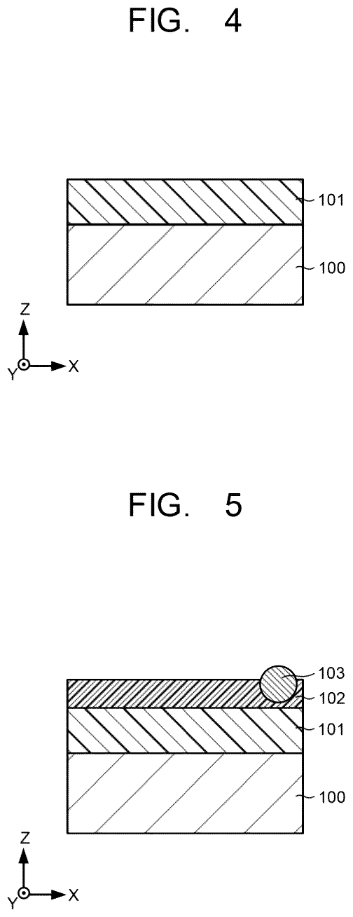

Next, a first embodiment of a pattern forming method using a template and a method of manufacturing a semiconductor device will be explained. FIG. 4 to FIG. 13 are schematic cross-sectional views for explaining the first embodiment. FIG. 4 to FIG. 13 illustrate a part of an X-Z cross-section of the object 100 in the shot area 110.

In the first embodiment, as illustrated in FIG. 4, an organic layer 101 is formed above the object 100. The organic layer 101 may be formed on a plurality of the shot areas 110 of the object 100.

The organic layer 101 is an uncured layer containing an uncured material of a first photocurable composition. The uncured material also includes a semi-cured material which is not completely cured. Examples of the first photocurable composition include ultraviolet curable organic materials. Examples of the first photocurable composition include an spin on carbon (SOC) film. Examples of the organic materials include resist materials containing an acrylic group or a methacrylic group. A viscosity of the uncured material in the first photocurable composition is, for example, 100 mPads or more and 1000000 mPa's or less at a temperature of 25° C.

The organic layer 101 can be formed by supplying a material containing the uncured material of the first photocurable composition to the surface of the object 100 using, for example, a spin coating method or an ink-jet method.

The viscosity of the organic layer 101 is preferably, for example, 100 mPa's or more and 1000 mPa's or less under the environment in forming the organic layer 101. The organic layer 101 and the object 100 may be bonded by forming an adhesive layer before the formation of the organic layer 101 and forming the organic layer 101 on the adhesive layer. The adhesive layer may be, for example, a film containing carbon, and may contain, for example, a functional group such as a hydroxyl group (OH group), a carboxyl group (COOH group), or an amino group (NH₂ group).

Next, as illustrated in FIG. 5, a resist layer 102 is formed on the organic layer 101. The resist layer 102 is an uncured layer containing an uncured material of a second photocurable composition different in composition from the first photocurable composition. Examples of the second photocurable composition include an ultraviolet curable resist material. The resist material may contain at least one element selected from the group consisting of silicon, aluminum, boron, phosphorus, sulfur, arsenic, and iron.

The resist layer 102 can be formed by supplying a material containing the uncured material of the second photocurable composition to the surface of the object 100 using, for example, the spin coating method or the ink-jet method.

The viscosity of the organic layer 101 is preferably higher than the viscosity of the resist layer 102 under the environment in forming the resist layer 102. This can prevent mixture of the first and second photocurable compositions in an interface between the organic layer 101 and the resist layer 102. The viscosity of the organic layer 101 may be adjusted by applying light having a light intensity, which is lower than a light intensity when applying light through a later-explained template, to the organic layer 101 before the formation of the resist layer 102 to increase the viscosity. The organic layer 101 at the time when the resist layer 102 is formed is an uncured layer which is not completely cured (or a semi-cured layer), and has viscous property.

FIG. 5 further illustrates a foreign matter 103. Above at least one shot area 110 of the shot areas 110, the foreign matter 103 may exist as illustrated in FIG. 5, for example, in or after the formation of the resist layer 102. The foreign matter 103 is exposed, for example, inside or on the resist layer 102. A part of the foreign matter 103 may be inside the organic layer 101. Examples of the foreign matter 103 include a particle (foreign particle). The particle has a composition different from the composition of each of the organic layer 101 and the resist layer 102. The particle contains, for example, at least one element selected from metal elements and carbon element.

A maximum particle size of the particle is, for example, 30 nm or more and less than 400 nm. A plurality of the foreign matters 103 may be exposed inside or on the resist layer 102.

The thickness of the organic layer 101 is preferably larger than the maximum particle size of the particle. The thickness of the organic layer 101 is, for example, 100 nm or more and 400 nm or less.

The thickness of the resist layer 102 may be smaller than the thickness of the organic layer 101. The thickness of the resist layer 102 is, for example, 0.03 μm or more and 0.15 μm or less.

The thickness of the organic layer 101, the thickness of the resist layer 102, and the maximum particle size of the particle can be measured in a cross-sectional reflection electron image, the cross-sectional reflection electron image being obtained, for example, by observing a cross-section including a thickness direction (Z-axis direction) of a sample including the object 100, the organic layer 101, and the resist layer 102 using a scanning electron microscope (SEM).

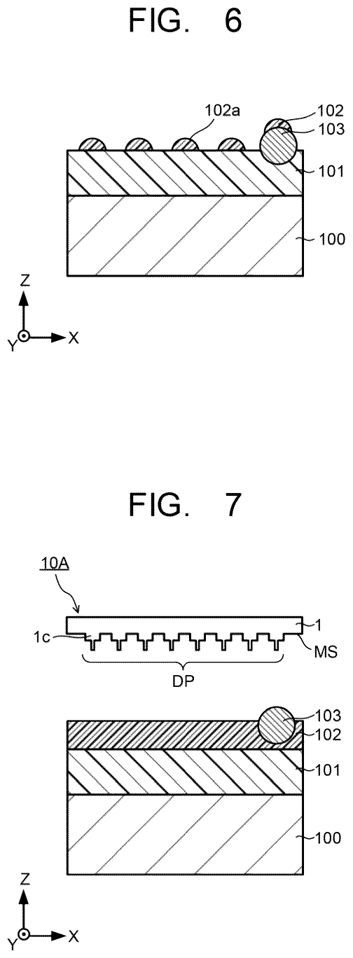

In the case of forming the resist layer 102 using the ink-jet method, the resist layer 102 may be formed by discharging a droplet 102a of a material containing the uncured material of the second photocurable composition. FIG. 6 illustrates a plurality of droplets 102a on the organic layer 101. In this event, the foreign matter 103 may be exposed, for example, to the surface of the organic layer 101.

Next, as illustrated in FIG. 7, a template 10A is arranged above the resist layer 102. For the explanation of the template 10A, the explanation of the template 10 can be used where appropriate. The template 10A is arranged so that the surface la is located facing downward. The movements of the template 10A and the object 100 can be controlled using, for example, the imprint apparatus.

The template 10A further has a protrusion 1c on the surface of the mesa MS of the substrate 1. The protrusion 1c forms a device pattern DP. FIG. 7 illustrates a plurality of the protrusions 1c, but the number of the protrusions 1c is not limited to the number illustrated in FIG. 7. Further, the template 10A may further have a plurality of depressions on the surface of the mesa MS.

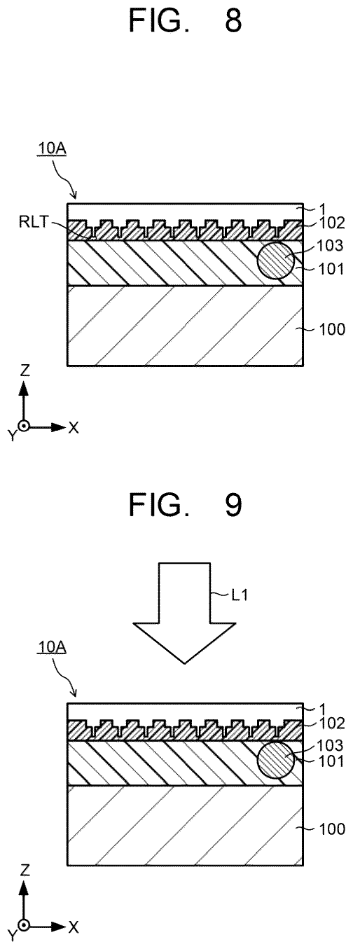

Next, as illustrated in FIG. 8, the template 10A is pressed against the resist layer 102 and the device pattern DP of the template 10A is filled with the resist layer 102 to mold the resist layer 102. The template 10A may be pressed against the resist layer 102 so that a residual film RLT of the resist layer 102 is formed, for example, between the protrusion 1c and the object 100. In this case, part of the particle may be exposed from the surface of the organic layer 101 to remain inside the resist layer 102. The maximum particle size of the particle is, for example, larger than the thickness of the residual film RLT. The thickness of the residual film RLT is, for example, 10 nm or more and 30 nm or less. The maximum particle size of the particle being the foreign matter 103 is, for example, larger than the thickness of the residual film RLT and smaller than the thickness of the organic layer 101.

In the case where the foreign matter 103 exists, the protrusion 1c comes into contact with the foreign matter 103, but the organic layer 101 is the uncured layer and has a viscosity at such a degree that the foreign matter 103 can move, so that at least part of the foreign matter 103 moves into the organic layer 101. The whole foreign matter 103 may be moved to into the organic layer 101 as illustrated in FIG. 8.

Next, as illustrated in FIG. 9, light L1 is applied through the template 10A with the template 10A being pressed against the molded resist layer 102 to cure the organic layer 101 and the resist layer 102, thereby fixing the foreign matter 103. Examples of the light L1 include ultraviolet light. The light L1 has a wavelength capable of sensitizing the first photocurable composition and the second photocurable composition.

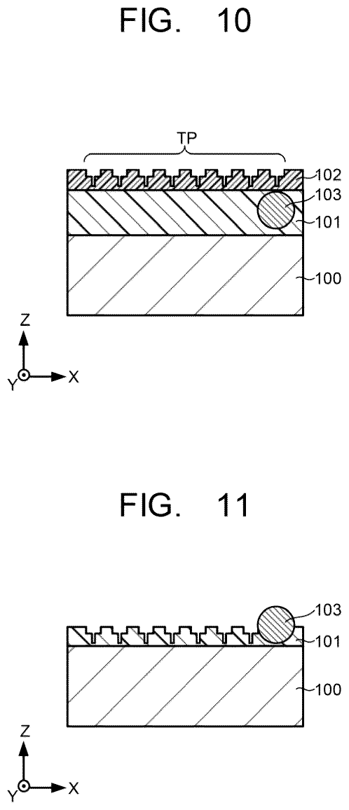

Next, as illustrated in FIG. 10, the template 10A is separated from the resist layer 102. This can form a cured resist layer 102 including a transferred pattern TP of the device pattern DP and a cured organic layer 101. The viscosity of the organic layer 101 cured by the application of the light LI becomes higher than that before the application of the light L1, and is, for example, more than 1000 mPa's and 1000000 mPa's or less.

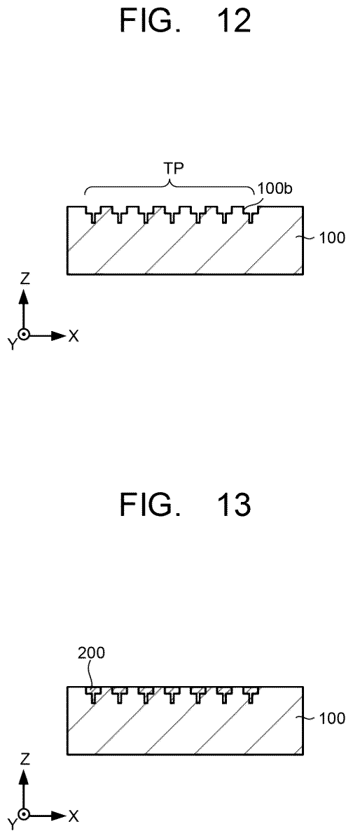

Next, as illustrated in FIG. 11, the organic layer 101 is processed using the cured resist layer 102, and the object 100 is processed using the cured and processed organic layer 101, whereby the transferred pattern TP including a depression 100b is formed on the object 100 as illustrated in FIG. 12. This forms a desired pattern on the object 100. The depression 100b may have an inverted shape of the protrusion 1c. In this event, in an area of the object 100 located under the foreign matter 103, no pattern is formed. This area becomes an area (defective chip) which cannot be used as a semiconductor device. The object 100 can be processed by partially removing the object 100 and the organic layer 101 by dry etching using the cured organic layer 101 and the cured resist layer 102. Examples of the dry etching include reactive ion etching (RIE). The remainder of the organic layer 101 after the processing and the foreign matter 103 are removed thereafter.

The object 100 and the organic layer 101 may be processed in stages by a plurality of times of etching. In this event, the organic layer 101 and the resist layer 102 having different etching rates is preferable because even a complicated pattern having a plurality of depressions and/or protrusions having different heights can be easily formed. For example, the composition of the organic layer 101 is made different from the composition of the resist layer 102, thereby making it possible to give etching rates different between the organic layer 101 and the resist layer 102.

Next, a metal material is buried in the depression 100b of the transferred pattern TP to form a conductor 200 as illustrated in FIG. 13. The metal material contains, for example, at least one metal element selected from the group consisting of copper, aluminum, tungsten, and titanium. The conductor 200 has a function, for example, as wiring having a dual damascene structure.

By the above process, a semiconductor device can be manufactured.

As explained above, the first embodiment includes pressing the foreign matter 103 inside or on the resist layer 102 by the device pattern DP of the template 10A to move at least part of the foreign matter 103 into the organic layer 101.

If the organic layer 101 is cured, the resist layer 102 is formed on the cured organic layer 101, and then the template 10A is pressed against the resist layer 102, the foreign matter 103 cannot be moved into the organic layer 101 and the foreign matter 103 comes into contact with the device pattern DP of the template 10A to break the template 10A in some cases. If the template 10A is broken, it becomes difficult to form the predetermined device pattern DP thereafter. This needs to add an inspection step of confirming the presence or absence of the foreign matter 103 is provided before pressing the template 10A, and if the foreign matter 103 exists, processing of not pressing the template 10A against the resist layer 102 for the corresponding shot area 110.

In contrast to the above, in the first embodiment, the organic layer 101 is the uncured layer and has a viscosity at such a degree that the foreign matter 103 can move when the template 10A is pressed against the resist layer 102, so that by bringing the device pattern DP of the template 10A into contact with the foreign matter 103, it is possible to mold the resist layer 102 and move at least part of the foreign matter 103 into the organic layer 101. This can prevent the breakage of the template 10A.

Further, in the first embodiment, any inspection step for confirming the presence or absence of the foreign matter 103 after forming the organic layer 101 and before pressing the template 10A against the resist layer 102 can be made unnecessary even if the foreign matter 103 exists, so that it is possible to simplify the manufacturing process of the semiconductor device without including the inspection step.

### Further Embodiment of First Embodiment

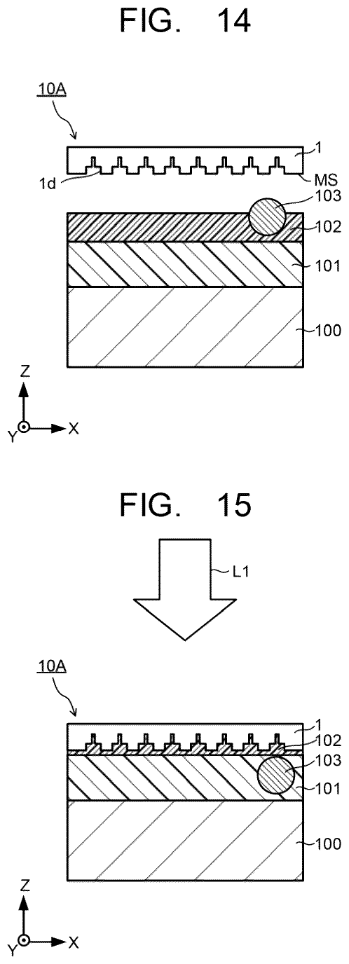

Next, a further embodiment of the first embodiment will be explained. FIG. 14 to FIG. 17 are schematic cross-sectional views for explaining the further embodiment of the first embodiment. FIG. 14 to FIG. 17 illustrate a part of an X-Z cross-section of the object 100.

In the further embodiment of the first embodiment, the template 10A is arranged so that the surface of the mesa MS faces downward, above the resist layer 102 as illustrated in FIG. 14 as in the first embodiment. The further embodiment of the first embodiment is different in shape of the device pattern of the template 10A as compared with the first embodiment. In the following, differences from the first embodiment will be explained, and for the other portions, the explanation in the first embodiment can be used where appropriate.

The template 10A has a depression 1d on the surface la. The depression 1d is provided on the surface of the mesa MS and forms the device pattern DP. The device pattern DP including the depression 1d may be an inverted pattern of the device pattern DP including the protrusion 1c. FIG. 14 illustrates a plurality of the depressions 1d, but the number of the depressions 1d is not limited to the number illustrated in FIG. 14. The template 10A may further have a plurality of protrusions on the mesa MS. For the other explanation of the template 10A, the explanation of the template 10A in the first embodiment can be used where appropriate.

Next, the template 10A is pressed against the organic layer 101 as in the first embodiment to mold the resist layer 102, and the light L1 is applied through the template 10A while the template 10A being pressed against the molded resist layer 102 as illustrated in FIG. 15 to cure the organic layer 101 and the resist layer 102.

Thereafter, as in the first embodiment, the organic layer 101 is processed using the cured resist layer 102, and the object 100 is processed using the cured and processed organic layer 101, whereby the transferred pattern TP is formed on the object 100.

As explained above, in the further embodiment of the first embodiment, the organic layer 101 is the uncured layer and has a viscosity at such a degree that the foreign matter 103 can move when the template 10A is pressed against the resist layer 102 as in the first embodiment, so that by bringing the device pattern DP of the template 10A into contact with the foreign matter 103, it is possible to mold the resist layer 102 and move at least part of the foreign matter 103 into the organic layer 101. This can prevent the breakage of the template 10A.

Further, in the further embodiment of the first embodiment, any inspection step

for confirming the presence or absence of the foreign matter 103 after forming the organic layer 101 and before pressing the template 10A against the resist layer 102 is made unnecessary even if the foreign matter 103 exists, so that it is possible to simplify the manufacturing process of the semiconductor device without including the inspection step.

### Second Embodiment

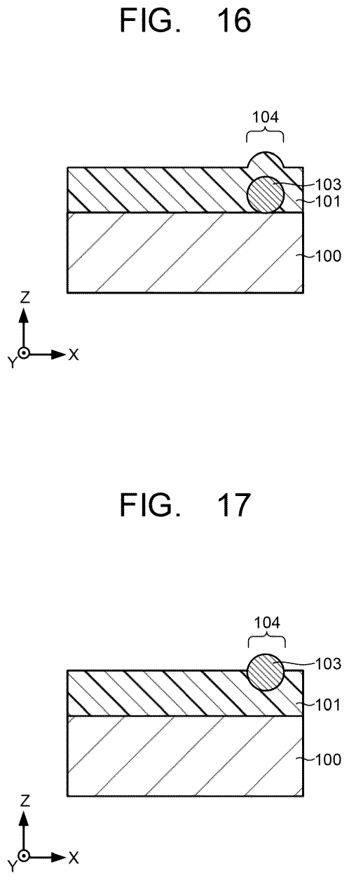

Next, a second embodiment of a pattern forming method using a template and a method of manufacturing a semiconductor device will be explained. FIG. 16 to FIG. 21 are schematic cross-sectional views for explaining the second embodiment. FIG. 16 to FIG. 21 illustrate a part of an X-Z cross-section of the object 100.

In the second embodiment, the organic layer 101 is formed on the object 100 as in the first embodiment. For the explanation of the object 100 and the organic layer 101, the explanation of the object 100 and the organic layer 101 in the first embodiment can be used where appropriate.

Above at least one shot area 110 of the shot areas 110, the foreign matter 103 may exist in some cases as illustrated in FIG. 16 or FIG. 17 in or after the formation of the organic layer 101. The foreign matter 103 is exposed, for example, inside or on the organic layer 101. For the other explanation of the foreign matter 103, the explanation of the foreign matter 103 in the first embodiment can be used where appropriate.

FIG. 16 and FIG. 17 further illustrate a protrusion 104 formed due to the foreign matter 103. The protrusion 104 is formed on the surface of the organic layer 101. The protrusion 104 may be formed including part of the organic layer 101 because part of the organic layer 101 protrudes due to the foreign matter 103, for example, as illustrated in FIG. 16, or may be formed including part of the foreign matter 103 because of the foreign matter 103 protrudes from the surface of the organic layer 101 as illustrated in FIG. 17.

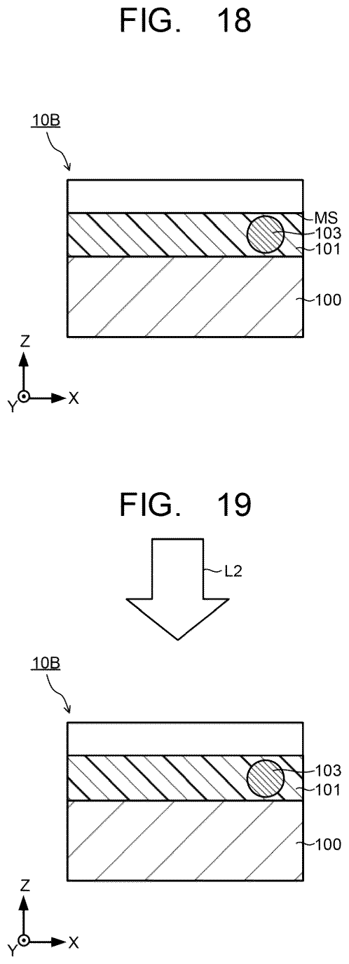

Next, a template 10B is arranged above the organic layer 101, and then the template 10B is pressed against the organic layer 101 to mold the organic layer 101 as illustrated in FIG. 18.

For the explanation of the template 10B, the explanation of the template 10 can be used where appropriate. The template 10B is arranged so that the surface of the mesa MS is located facing downward. The movements of the template 10B and the object 100 can be controlled using, for example, the imprint apparatus.

The template 10B has no pattern on the mesa MS. The surface la includes the surface of the mesa MS. The surface of the mesa MS of the template 10B is preferably flat.

By pressing the template 10B against the resist layer 102, the protrusion 104 is pressed by the surface of the mesa MS of the template 10B. This can eliminate the protrusion 104 to make the surface (upper surface) of the organic layer 101 flat. In this event, the foreign matter 103 may be moved into the organic layer 101. The whole foreign matter 103 may be moved into the organic layer 101.

Next, as illustrated in FIG. 19, light L2 is applied through the template 10B with the template 10B being pressed against the molded organic layer 101 to cure the organic layer 101. This can fix the foreign matter 103 inside the organic layer 101. Examples of the light L2 include ultraviolet light. The light L2 has a wavelength capable of sensitizing the first photocurable composition.

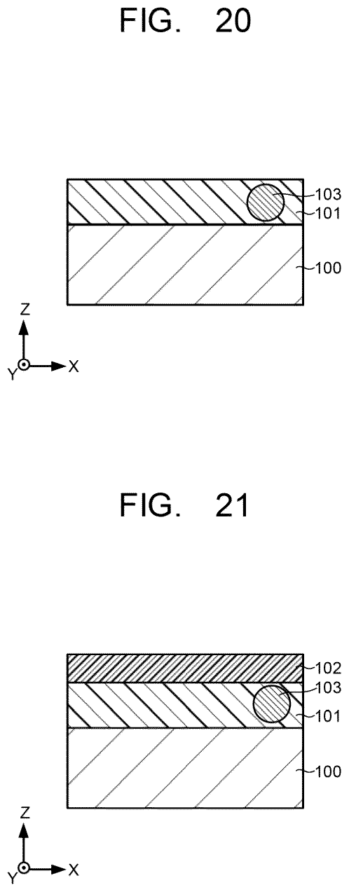

Next, as illustrated in FIG. 20, the template 10B is separated from the organic layer 101. This can form a flattened and cured organic layer 101. The surface roughness can be measured from a cross-sectional reflection electron image obtained, for example, by observing a cross-section including a thickness direction (Z-axis direction) of a sample including the object 100 and the organic layer 101 using the SEM.

Next, the resist layer 102 is formed on the flattened and cured organic layer 101 as illustrated in FIG. 21. For the other explanation of the resist layer 102, the explanation of the resist layer 102 in the first embodiment can be used where appropriate.

Next, the template 10A is pressed against the resist layer 102 to mold the resist layer 102 by the same method as in the first embodiment, and the light L1 is applied through the template 10A with the template 10A being pressed against the molded resist layer 102 to cure the resist layer 102. The device pattern DP of the template 10A may include the depression 1d as in the further embodiment of the first embodiment.

Thereafter, by the same method as in the first embodiment, the organic layer 101 is processed using the cured resist layer 102, and the object 100 is processed using the cured organic layer 101, whereby the transferred pattern TP of the device pattern DP is formed on the object 100. The object 100 can be processed by partially removing the object 100, the organic layer 101, and the resist layer 102 by dry etching such as RIE using the cured organic layer 101 and the cured resist layer 102. The remainder of the organic layer 101 after the processing and the foreign matter 103 are removed thereafter.

Next, a metal material is buried in the depression 100b by the same method as in the first embodiment to form the conductor 200.

By the above process, a semiconductor device can be manufactured.

As explained above, the second embodiment includes pressing the protrusion 104 formed on the organic layer 101 due to the foreign matter 103 inside or on the organic layer 101 by the template 10B having the flat surface with no pattern to flatten the upper surface of the organic layer 101, forms the resist layer 102 on the flattened organic layer 101, and then performs imprint using the template 10A having a pattern.

If the resist layer 102 is formed on the organic layer 101 with the protrusion 104 remaining and the template 10A is then pressed against the resist layer 102, the protrusion 104 comes into contact with the template 10A after the curing of the organic layer 101 to break the template 10A in some cases. If the template 10A is broken, it becomes difficult to form the desired device pattern DP thereafter. Therefore, an inspection step of confirming the presence or absence of the foreign matter 103 is provided before pressing the template 10A, and if the foreign matter 103 exists, processing of not pressing the template 10A against the resist layer 102 for the corresponding shot area 110 is necessary.

In contrast to the above, in the second embodiment, the surface of the organic layer 101 is flattened before the template 10A is pressed against the resist layer 102, thereby making it possible to prevent the breakage of the template 10A even if the template 10A is pressed against the resist layer 102 after the curing of the organic layer 101.

Further, in the second embodiment, any inspection step for confirming the presence or absence of the foreign matter 103 after forming the organic layer 101 and before pressing the template 10A against the resist layer 102 can be made unnecessary even if the foreign matter 103 exists, so that it is possible to simplify the manufacturing process of the semiconductor device without including the inspection step.

The second embodiment can be appropriately combined with the first embodiment.

While certain embodiments of the present invention have been described above, these embodiments have been presented by way of example only, and are not intended to limit the scope of the invention. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A pattern forming method, comprising:
forming a first layer on an object, the first layer containing a first photocurable composition;
forming a second layer on the first layer, the second layer containing a second photocurable composition different in composition from the first photocurable composition;
pressing a first template having a surface with a pattern against the second layer to bring the pattern into contact with a foreign matter inside or on a surface of the second layer, thereby moving at least part of the foreign matter into the first layer; and
applying a first light to the first layer and the second layer through the first template to cure the first layer and the second layer.

2. The method according to claim 1, wherein
the first layer is formed by supplying the first photocurable composition onto the object using a spin coating method or an ink-jet method.

3. The method according to claim 1, wherein
the second layer is formed by supplying the second photocurable composition onto the object using a spin coating method or an ink-jet method.

4. The method according to claim 1, wherein
the first photocurable composition contains an ultraviolet curable organic material.

5. The method according to claim 1, wherein
the second photocurable composition contains at least one element selected from the group consisting of silicon, aluminum, boron, phosphorus, sulfur, arsenic, and iron.

6. The method according to claim 1, wherein:
the foreign matter is a particle; and
a thickness of the first layer is larger than a maximum particle size of the particle.

7. The method according to claim 1, wherein
a viscosity of the first layer is higher than a viscosity of the second layer in forming the second layer.

8. A pattern forming method comprising:
forming a first layer on an object, the first layer containing an uncured material of a first photocurable composition;
pressing a first template having a flat surface against the first layer to flatten an upper surface of the first layer, the protrusion being caused by a foreign matter inside or on a surface of the first layer;
applying a first light to the first layer through the first template to cure the first layer;
forming a second layer on the cured first layer, the second layer containing an uncured material of a second photocurable composition different in composition from the first photocurable composition;
pressing a second template having a surface with a pattern against the second layer to bring the pattern into contact with the second layer; and
applying a second light to the second layer through the second template to cure the second layer.

9. The method according to claim 8, wherein
the first layer is formed by supplying the first photocurable composition onto the object using a spin coating method or an ink-jet method.

10. The method according to claim 8, wherein
the second layer is formed by supplying the second photocurable composition onto the object using a spin coating method or an ink-jet method.

11. The method according to claim 8, wherein
the first photocurable composition contains an ultraviolet curable organic material.

12. The method according to claim 8, wherein
the second photocurable composition contains at least one element selected from the group consisting of silicon, aluminum, boron, phosphorus, sulfur, arsenic, and iron.

13. The method according to claim 8, wherein:
the foreign matter is a particle; and
a thickness of the first layer is larger than a maximum particle size of the particle.

14. The method according to claim 8, wherein
a viscosity of the first layer is higher than a viscosity of the second layer in forming the second layer.

15. A method of manufacturing a semiconductor device, comprising:
forming a first cured layer and a second cured layer on a substrate by a first pattern forming method or a second pattern forming method; and
etching the substrate using the first cured layer and the second cured layer to partially remove the substrate,
the first pattern forming method comprising:
forming a first layer on the substrate, the first layer containing a first photocurable composition;
forming a second layer on the first layer, the second layer containing a second photocurable composition different in composition from the first photocurable composition;
pressing a first template having a surface with a pattern against the second layer to bring the pattern into contact with a foreign matter inside or on a surface of the second layer, thereby moving at least part of the foreign matter into the first layer; and
applying a first light to the first layer and the second layer through the first template to cure the first layer and the second layer, and
the second pattern forming method comprising:
forming a third layer on the substrate, the third layer containing an uncured material of the first photocurable composition;
pressing a second template having a flat surface against the third layer to flatten an upper surface of the third layer, the protrusion being caused by the foreign matter;
applying a second light to the third layer through the second template to cure the third layer;
forming the fourth layer on the cured third layer;
pressing the first template against the fourth layer to bring the pattern into contact with the fourth layer; and
applying the first light to the fourth layer through the first template to cure the fourth layer.

16. The method according to claim 15, wherein
the first layer or the third layer is formed by supplying the first photocurable composition onto the substrate using a spin coating method or an ink-jet method, and
the second layer or the fourth layer is formed by supplying the second photocurable composition onto the substrate using a spin coating method or an ink-jet method.

17. The method according to claim 15, wherein
the first photocurable composition contains an ultraviolet curable organic material.

18. The method according to claim 15, wherein
the second photocurable composition contains at least one element selected from the group consisting of silicon, aluminum, boron, phosphorus, sulfur, arsenic, and iron.

19. The method according to claim 15, wherein:
the foreign matter is a particle; and
a thickness of the first layer or the third layer is larger than a maximum particle size of the particle.

20. The method according to claim 15, wherein
a viscosity of the first layer is higher than a viscosity of the second layer in forming the second layer, and
a viscosity of the third layer is higher than a viscosity of the fourth layer in forming the fourth layer.
